(19) United States
(12) Patent Application Publication
(10) Pub. No.: US 2026/0169625 A1
(43) Pub. Date: Jun. 18, 2026

(54) CONTROLLER, MEMORY DEVICE AND STORAGE DEVICE

(71) Applicant: SK hynix Inc., Icheon-si (KR)

(72) Inventor: Eun Jae OCK, Icheon-si (KR)

(21) Appl. No.: 19/228,544

(22) Filed: Jun. 4, 2025

(30) Foreign Application Priority Data
Dec. 12, 2024 (KR) 10-2024-0184316

(51) Int. Cl. G06F 3/06

(52) U.S. Cl. CPC G06F 3/061; G06F 3/0659; G06F 3/0673

(57) ABSTRACT

A storage device includes a memory including a first file storage area where a first file is stored and a controller. Such a controller may perform one or more first read operations using a first read voltage on a first portion of the first file storage area. The controller may, when a specific one of the first read operations fails, search for a second read voltage and perform one or more second read operations using the second read voltage on a second portion of the first file storage area other than the first portion.

### CROSS-REFERENCE TO RELATED APPLICATION

The present application claims priority under 35 U.S.C. § 119(a) to Korean Patent Application No. 10-2024-0184316 filed in the Korean Intellectual Property Office on Dec. 12, 2024, which is incorporated herein by reference in its entirety.

### BACKGROUND

### 1. Technical Field

Embodiments of the present disclosure relate to a controller, a memory device, and a storage device.

### 2. Related Art

A storage device may include at least one memory which stores data. The storage device may include a controller which controls the operation of the memory. For example, according to a command received from a host device, the controller may control an operation of writing, reading, or erasing data.

The memory may include a plurality of memory cells which store data. Data may be written to each of the plurality of memory cells, and the written data may be read. Due to use of the memory, the characteristics of the plurality of memory cells may change, and the operational performance of the memory such as in a read operation may deteriorate.

### SUMMARY

The tasks of embodiments of the present disclosure are not limited to the tasks mentioned in this specification, and other tasks not mentioned can be understood by those skilled in the art in light of the description of the present disclosure.

Embodiments of the present disclosure are directed to providing measures capable of efficiently performing a read retry operation when a read operation on data stored in a memory included in a storage device fails.

In an embodiment, a storage device may include: a memory including a first file storage area where a first file is stored; and a controller configured to perform one or more first read operations using a first read voltage on a first portion of the first file storage area and configured to, when a specific one of the first read operations fails, search for a second read voltage and perform one or more second read operations using the second read voltage on a second portion of the first file storage area other than the first portion.

In an embodiment, a memory device may include: a first file storage area including a plurality of first word lines and storing a first file therein; and a second file storage area including a plurality of second word lines and storing a second file therein, wherein, according to a first read command for the first file, one or more first read operations using a first read voltage are performed on a first group of the plurality of first word lines, and one or more second read operations using a second read voltage is performed on a second group of the plurality of first word lines.

In an embodiment, a controller may include: a command receiving circuit configured to receive a read command and information on a file according to the read command; and a read operation control circuit configured to control one or more first read operations using a first read voltage on a first portion of a first file storage area storing the file, and configured to, when a specific one of the first read operations fails, search for a second read voltage and control one or more second read operations using the second read voltage on a second portion of the first file storage area other than the first portion.

According to the embodiments of the present disclosure, the operational performance of a storage device may be improved by preventing or reducing delay due to a read retry operation when a read operation on a memory fails and increase in load due to management of read voltages.

Effects of the embodiments of the present disclosure are not limited to those mentioned above, and other effects not mentioned may be understood by those skilled in the art from the description of claims.

### BRIEF DESCRIPTION OF THE DRAWINGS

Embodiments of the present disclosure will be more fully understood from the detailed description to be made below and the accompanying drawings, which are provided for illustration only and are not intended to limit various embodiments of the present disclosure.

FIG. 1 is a diagram illustrating a schematic configuration of a storage device according to embodiments of the present disclosure.

FIG. 2 is a diagram illustrating a schematic configuration of a memory according to embodiments of the present disclosure.

FIG. 3 is a diagram illustrating a schematic structure of a memory cell array according to embodiments of the present disclosure.

FIG. 4 is a diagram illustrating a configuration of a storage device which performs a read retry operation by a unit of file, according to embodiments of the present disclosure.

FIGS. 5, 6, 7, and 8 are diagrams each illustrating a method in which a read retry operation is performed by the storage device illustrated in FIG. 4 according to embodiments of the present disclosure.

FIG. 9 and FIG. 10 are diagrams each illustrating a method in which a read retry operation is performed in the memory of the storage device illustrated in FIG. 4 according to embodiments of the present disclosure.

### DETAILED DESCRIPTION

In the following description of examples or embodiments of the present disclosure, reference will be made to the accompanying drawings in which it is shown by way of illustration specific examples or embodiments that can be implemented, and in which the same reference numerals and signs can be used to designate the same or like components even when they are shown in different accompanying drawings from one another. Further, in the following description of examples or embodiments of the present disclosure, detailed descriptions of well-known functions and components incorporated herein may be omitted for the interest of brevity. The terms such as “including,” “having,” “containing,” “constituting,” “make up of,” and “formed of” used herein are generally intended to allow other components to be added unless the terms are used with the term “only.” As used herein, singular forms are intended to include plural forms unless the context clearly indicates otherwise.

Terms, such as “first,” “second,” “A,” “B,” “(A),” or “(B)” may be used herein to describe elements of the present disclosure. Each of these terms is not used to define essence, order, sequence, or number of elements etc., but is used merely to distinguish the corresponding element from other elements.

When a first element “is connected or coupled to,” “contacts or overlaps” etc. a second element, not only can the first element “be directly connected or coupled to” or “directly contact or overlap” the second element, but a third element can also be “interposed” between the first and second elements, or the first and second elements can “be connected or coupled to,” “contact or overlap,” etc. each other via a fourth element. Here, the second element may be included in at least one of two or more elements that “are connected or coupled to,” “contact or overlap,” etc. each other.

When time relative terms, such as “after,” “subsequent to,” “next,” “before,” and the like, are used to describe processes or operations of elements or configurations, or flows or steps in operating, processing, manufacturing methods, these terms may be used to describe non-consecutive or non-sequential processes or operations unless the term “directly” or “immediately” is used together.

In addition, when any dimensions, relative sizes etc. are mentioned, it should be considered that numerical values for an elements or features, or corresponding information (e.g., level, range, etc.) include a tolerance or error range that may be caused by various factors (e.g., process factors, internal or external impact, noise, etc.) even when a relevant description is not specified. Further, the term “may” encompasses the meanings of the term “can.”

Hereinafter, some embodiments of the present disclosure will be described in detail with reference to accompanying drawings. Throughout the specification and claims, a list of items prefaced by a phrase such as “at least one of” or “one or more of” or “one or both of” indicates an inclusive list. For example, a list of “at least one of A or B” and a list of “one or both of A and B” each indicate A, or B, or AB (i.e., A and B).

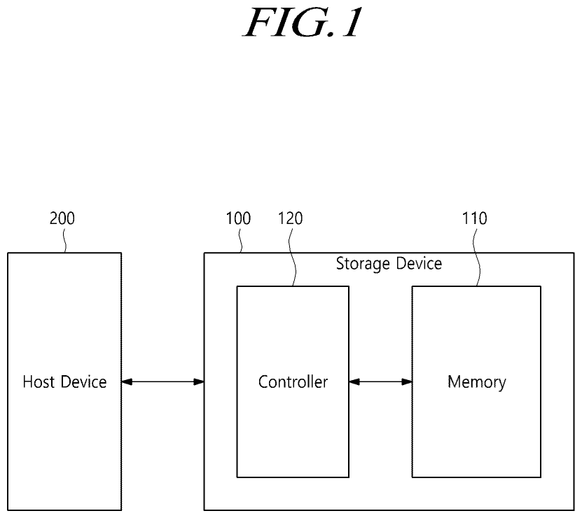

FIG. 1 is a diagram illustrating a schematic configuration of a storage device 100 according to embodiments of the present disclosure.

Referring to FIG. 1, the storage device 100 according to the embodiments of the present disclosure may include at least one memory 110. The storage device 100 may include a controller 120 which controls the operation of the memory 110.

The memory 110 may be, for example, volatile memory such as DRAM, SDRAM, DDR SDRAM and LPDDR SDRAM, but the embodiments of the present disclosure are not limited thereto. The memory 110 may be nonvolatile memory such as NAND flash memory, 3D NAND flash memory and NOR flash memory.

As the case may be, one part of the memory 110 included in the storage device 100 may be volatile memory, and the other part of the memory 110 may be nonvolatile memory. In this case, data may be stored in nonvolatile memory, and volatile memory may be used to store data required for the operation of nonvolatile memory. Alternatively, volatile memory may perform the function of cache memory.

In addition, the memory 110 may be one of various types of memory such as resistive RAM, phase change memory, magnetoresistive memory, ferroelectric memory and spin transfer torque memory. As the case may be, the memory 110 may be processing-in-memory which includes a computation function or a data processing function.

The memory 110 may include a plurality of memory cells which store data. Two or more memory cells may constitute a single page. Two or more pages may constitute a single unit storage area. In the present specification, the memory 110 may also be referred to as a memory device.

The controller 120 may receive a command from the outside, and may control the operation of the memory 110 on the basis of the received command. In addition, the controller 120 may control the operation of the memory 110 on the basis of an internally generated command. In the present specification, a command which the controller 120 receives from the outside thereof may be referred to as an external command, and a command which is generated inside the controller 120 may be referred to as an internal command.

The controller 120 may control the operation of the memory 110 on the basis of the external command or the internal command. For example, the controller 120 may control an operation of writing data to the memory 110. The controller 120 may control an operation of reading data written to the memory 110. Data may be transmitted and received between the controller 120 and the memory 110.

Depending on the type of the memory 110, the controller 120 may control a data preservation operation (e.g., a refresh operation or a patrol scrub operation) or an erase operation on data written to the memory 110.

In order to maintain and improve the operational performance of the storage device 100, the controller 120 may perform a background operation related with the memory 110 on the basis of an external command received from an external host device 200 or on the basis of an internal command. The background operation may include at least one among, for example, garbage collection, wear leveling, read reclaim and bad block management operations. Through control of the background operation, the controller 120 may improve the operational performance of the storage device 100 or substantially prevent the operational performance of the storage device 100 from deteriorating.

The controller 120 may control the operation of the memory 110 on the basis of a command received from the host device 200. The controller 120 may provide the host device 200 with a processing result according to an operation corresponding to the command. The controller 120 may transmit data or a response signal to the host device 200.

For example, the host device 200 may be a computer, an ultra mobile PC (UMPC), a workstation, a personal digital assistant (PDA), a tablet, a mobile phone, a smartphone, an e-book, a portable multimedia player (PMP), a portable game player, a navigation device, a black box, a digital camera, a digital multimedia broadcasting (DMB) player, a smart television, a digital audio recorder, a digital audio player, a digital picture recorder, a digital picture player, a digital video recorder, a digital video player, a storage configuring a data center, one of various electronic devices configuring a home network, one of various electronic devices configuring a telematics network, an RFID (radio frequency identification) device, a mobility device (e.g., a vehicle, a robot or a drone) capable of traveling under human control or autonomous driving, etc. Alternatively, the host device 200 may be a virtual/augmented reality device which provides a 2D or 3D virtual reality image or augmented reality image. Besides, the host device 200 may be any one of various electronic devices each of which requires the storage device 100 capable of storing data.

The host device 200 may include at least one operating system. The operating system may manage and control overall functions and operations of the host device 200, and may control the interoperation between the host device 200 and the storage device 100. The operating system may be classified into a general operating system and a mobile operating system depending on the mobility of the host device 200.

The controller 120 and the host device 200 may be devices which are separated from each other. As the case may be, the controller 120 and the host device 200 may be implemented by being integrated as a single device, or some components or functions of the controller 120 may be implemented by being included in the host device 200. Hereunder, for the sake of convenience in explanation, it will be described as an example that the controller 120 and the host device 200 are devices which are separated from each other.

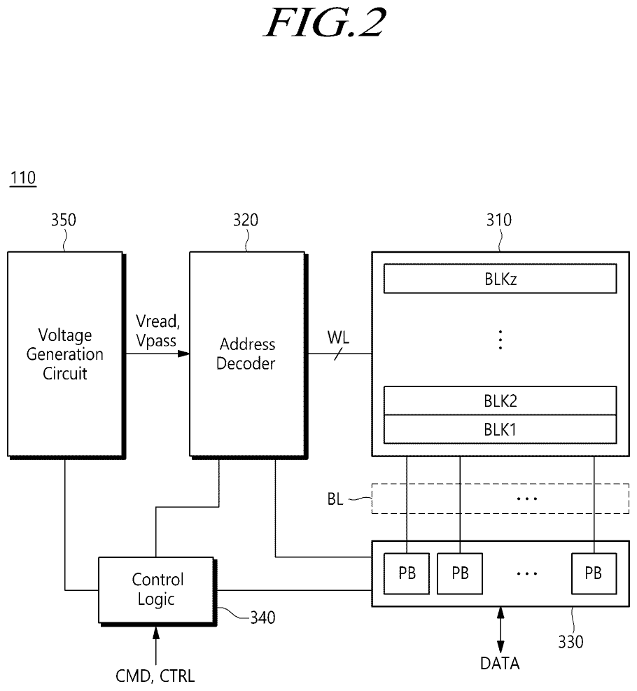

FIG. 2 is a diagram illustrating an example of the schematic configuration of the memory 100 according to embodiments of the present disclosure.

Referring to FIG. 2, the memory 110 according to the embodiments of the present disclosure may include a memory cell array 310, an address decoder 320, a read and write circuit 330, a control logic 340 and a voltage generation circuit 350.

The memory cell array 310 may include a plurality of storage blocks BLK1 to BLKz (z is a natural number of 2 or more).

In the plurality of storage blocks BLK, a plurality of word lines WL and a plurality of bit lines BL may be disposed, and a plurality of memory cells may be arranged. Two or more memory cells may constitute a single page. Each storage block BLK may include a plurality of pages. An operation of writing data or an operation of reading data may be performed by the unit of page.

The plurality of storage blocks BLK may be connected to the address decoder 320 through the plurality of word lines WL. The plurality of storage blocks BLK may be connected to the read and write circuit 330 through the plurality of bit lines BL.

Each of the plurality of storage blocks BLK may include a plurality of memory cells. The plurality of memory cells may be nonvolatile memory cells, and may be configured with nonvolatile memory cells which have a vertical channel structure.

The memory cell array 310 may be configured as a memory cell array with a two-dimensional structure, and as the case may be, may be configured as a memory cell array with a three-dimensional structure.

Each of the plurality of memory cells included in the memory cell array 310 may store at least 1 bit of data. For example, each of the plurality of memory cells included in the memory cell array 310 may be a single-level cell (SLC) which stores 1 bit of data. For another example, each of the plurality of memory cells included in the memory cell array 310 may be a multi-level cell (MLC) which stores 2 bits of data, a triple-level cell (TLC) which stores 3 bits of data, a quad-level cell (QLC) which stores 4 bits of data, or a memory cell which stores at least 5 bits of data.

The number of bits of data stored in each of the plurality of memory cells may be dynamically determined. For example, a single-level cell which stores 1 bit of data may be changed to a triple-level cell which stores 3 bits of data.

The address decoder 320, the read and write circuit 330, the control logic 340, and the voltage generation circuit 350 together may operate as a peripheral circuit which drives the memory cell array 310.

The address decoder 320 may be connected to the memory cell array 310 through the plurality of word lines WL. The address decoder 320 may be configured to operate in response to control of the control logic 340.

The address decoder 320 may receive an address through an input/output buffer in the memory 110. The address decoder 320 may be configured to decode a block address in the received address. The address decoder 320 may select at least one storage block BLK according to the decoded block address.

The address decoder 320 may receive a read voltage Vread and a pass voltage Vpass from the voltage generation circuit 350.

In a program operation, the address decoder 320 may apply a program voltage for the program operation to a word line WL which is a target of the program operation. The pass voltage Vpass may be applied to word lines WL other than the word line WL which is the target of the program operation. Data may be written to each memory cell according to a voltage supplied to a bit line BL connected to the word line WL to which the program voltage is applied.

In an operation of applying the read voltage Vread during a read operation, the address decoder 320 may apply the read voltage Vread to a selected word line WL in a selected storage block BLK, and may apply the pass voltage Vpass to remaining unselected word lines WL.

In a program verify operation, the address decoder 320 may apply a verify voltage generated in the voltage generation circuit 350 to a selected word line WL in a selected storage block BLK, and may apply the pass voltage Vpass to remaining unselected word lines WL.

The address decoder 320 may be configured to decode a column address in the received address. The address decoder 320 may transmit the decoded column address to the read and write circuit 330.

A read operation and a program operation of the memory 110 may be performed by the unit of page. An address received when each of the read operation and the program operation is requested may include at least one of a block address, a row address, or a column address.

The address decoder 320 may select a single storage block BLK and a single word line WL according to the block address and the row address. The column address may be decoded by the address decoder 320, and the decoded column address may be provided to the read and write circuit 330.

The address decoder 320 may include at least one of a block decoder, a row decoder, a column decoder, or an address buffer.

The read and write circuit 330 may include a plurality of page buffers PB. The read and write circuit 330 may operate as a read circuit in a read operation of the memory cell array 310, and may operate as a write circuit in a write operation of the memory cell array 310.

The read and write circuit 330 may also be referred to as a page buffer circuit or a data register circuit which includes the plurality of page buffers PB. The read and write circuit 330 may include a data buffer which takes charge of a data processing function, and as the case may be, may additionally include a cache buffer which takes charge of a caching function.

The plurality of page buffers PB may be connected to the memory cell array 310 through the plurality of bit lines BL. In order to sense threshold voltages (Vth) of memory cells in a read operation and a program verify operation, the plurality of page buffers PB may continuously supply sensing current to bit lines BL connected to the memory cells, and may latch sensing data by sensing, through sensing nodes, that amounts of current flowing according to programmed states of the corresponding memory cells change.

The read and write circuit 330 may operate in response to page buffer control signals outputted from the control logic 340.

In a read operation, the read and write circuit 330 may temporarily store read data by sensing data of memory cells, and then, may output data DATA to the input/output buffer of the memory 110. As an example embodiment, the read and write circuit 330 may include a column select circuit, etc. in addition to the page buffers PB or page registers.

The control logic 340 may be connected to the address decoder 320, the read and write circuit 330 and the voltage generation circuit 350. The control logic 340 may receive a command CMD and a control signal CTRL through the input/output buffer of the memory 110.

The control logic 340 may be configured to control overall operations of the memory 110 in response to the control signal CTRL. The control logic 340 may output control signals for adjusting the precharge potential levels of the sensing nodes of the plurality of page buffers PB.

The control logic 340 may control the read and write circuit 330 to perform a read operation of the memory cell array 310. The voltage generation circuit 350 may generate the read voltage Vread and the pass voltage Vpass used in the read operation, in response to a voltage generation circuit control signal outputted from the control logic 340.

Each of the storage blocks BLK of the memory 110 described above may be composed of a plurality of pages corresponding to a plurality of word lines WL and a plurality of strings corresponding to a plurality of bit lines BL.

In the storage block BLK, the plurality of word lines WL and the plurality of bit lines BL may be disposed to intersect each other. A memory cell which is connected to a corresponding one of the plurality of word lines WL and a corresponding one of the plurality of bit lines BL may be defined. A transistor may be disposed in each memory cell.

The transistor disposed in the memory cell may include a drain, a source, and a gate. The drain (or source) of the transistor may be connected to a corresponding bit line BL directly or via another transistor. The source (or drain) of the transistor may be connected to a source line (which may be the ground) directly or via another transistor. The gate of the transistor may include a floating gate which is surrounded by a dielectric and a control gate to which a gate voltage is applied from a word line WL.

In each storage block BLK, a select line (also referred to as a source select line or a drain select line) may be additionally disposed outside one outermost word line WL more adjacent to the read and write circuit 330 between two outermost word lines WL, and the other select line (also referred to as a drain select line or a source select line) may be additionally disposed outside the other outermost word line WL between the two outermost word lines WL.

As the case may be, at least one dummy word line may be additionally disposed between an outermost word line WL and a select line.

A read operation and a program operation (a write operation) for the storage block BLK described above may be performed by the unit of page, and an erase operation may be performed by the unit of storage block BLK.

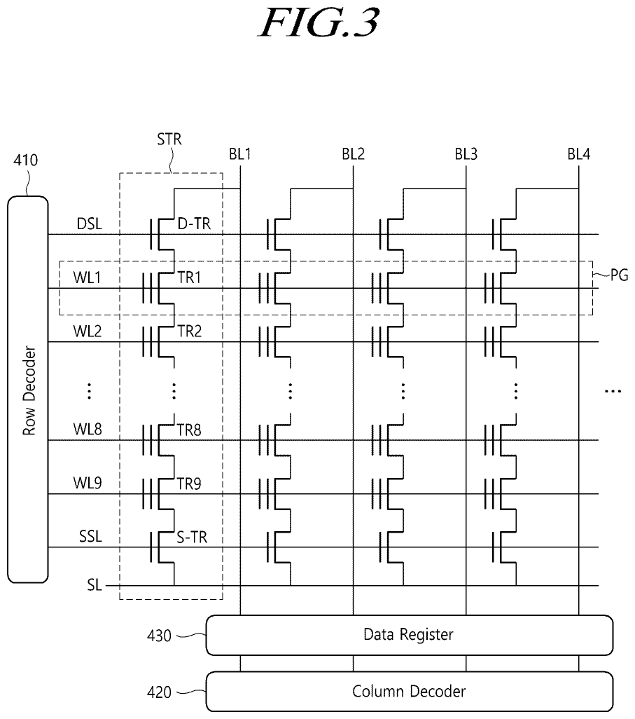

FIG. 3 is a diagram illustrating an example of the schematic structure of the memory cell array 310 according to embodiments of the present disclosure.

Referring to FIG. 3, the memory 110 may include a core area where memory cells are gathered and an auxiliary area which corresponds to the remaining area other than the core area and in which circuits for the operation of the memory cell array 310, etc. are disposed.

In the core area, a plurality of word lines WL1, . . . and WL9 and a plurality of bit lines BL1, . . . and BL4 may be disposed while intersecting each other. The number of word lines WL and the number of bit lines BL are not limited to those illustrated in FIG. 3. The number of word lines WL and the number of bit lines BL included in each storage block BLK may vary according to embodiments.

The plurality of word lines WL may be connected to a row decoder 410. The plurality of bit lines BL may be connected to a column decoder 420. A data register 430 corresponding to the read and write circuit 330 may be located between the plurality of bit lines BL and the column decoder 420.

Each of the plurality of word lines WL may correspond to a page. For example, as in the example illustrated in FIG. 3, each of the plurality of word lines WL may correspond to a single page. As the case may be, when memory cells operate as multi-level cells or triple-level cells, each of the plurality of word lines WL may correspond to two or more pages. Page may be a smallest unit by which a program operation and a read operation are performed. In a program operation and a read operation, all memory cells included in the same page may simultaneously operate.

The plurality of bit lines BL may be divided into, for example, odd bit lines BL and even bit lines BL and may be connected to the column decoder 420. Each of the plurality of bit lines BL may correspond to a string STR.

The string STR may include a plurality of transistors TR1, . . . and TR9 which are connected to the plurality of word lines WL. Areas where the plurality of transistors TR exist may correspond to memory cells. Each of the plurality of transistors TR may be a transistor which includes a control gate and a floating gate as described above.

The plurality of word lines WL may include two outermost word lines WL1 and WL9. A first select line DSL may be disposed outside a first word line WL1 which is located closer to the data register 430 in terms of signal path between the two word lines WL1 and WL9. The first word line WL1 may be referred to as a first outermost word line. A second select line SSL may be disposed outside a ninth word line WL9 between the two word lines WL1 and WL9. The ninth word line WL9 may be referred to as a second outermost word line. As the case may be, at least one dummy word line may be additionally disposed between the first outermost word line and the first select line DSL. At least one dummy word line may be additionally disposed between the second outermost word line and the second select line SSL.

A first select transistor D-TR, which is controlled by the first select line DSL to be turned on and off, may include a gate electrode which is connected to the first select line DSL. The first select transistor D-TR may not include a floating gate. A second select transistor S-TR, which is controlled by the second select line SSL to be turned on and off, may include a gate electrode which is connected to the second select line SSL. The second select transistor S-TR may not include a floating gate.

The first select transistor D-TR may play the role of a switch which turns on or off connection between the corresponding string STR and the data register 430. The second select transistor S-TR may play the role of a switch which turns on or off connection between the corresponding string STR and the source line SL.

In a program operation, a predetermined turn-on voltage may be applied to the gate electrode of the first select transistor D-TR, and the first select transistor D-TR may be turned on. A predetermined turn-off voltage may be applied to the gate electrode of the second select transistor S-TR, and the second select transistor S-TR may be turned off.

In a read operation or a verify operation, both the first select transistor D-TR and the second select transistor S-TR may be turned on. Current may flow through the string STR to the source line SL corresponding to the ground, and the voltage level of the bit line BL may be measured. In the read operation or the verify operation, there may be a time difference between the on and off timing of the first select transistor D-TR and the second select transistor S-TR.

In an erase operation, a predetermined voltage (e.g., 20V) may be supplied to a substrate through the source line SL. In the erase operation, the first select transistor D-TR and the second select transistor S-TR may be floated. As electrons move by the potential difference between floating gates and the substrate, data written to memory cells may be erased.

In this way, write, read and erase operations may be performed for memory cells included in the memory 110. When an operation for a memory cell fails, the controller 120 may retry the corresponding operation. For example, when a read operation on a memory cell fails, the controller 120 may perform a read retry operation of retrying a read operation. Due to the read retry operation, the operational performance of the memory 110 may deteriorate.

Embodiments of the present disclosure may provide measures capable of efficiently performing a read retry operation when a read operation on the memory 110 fails, thereby improving the operational performance of the storage device 100.

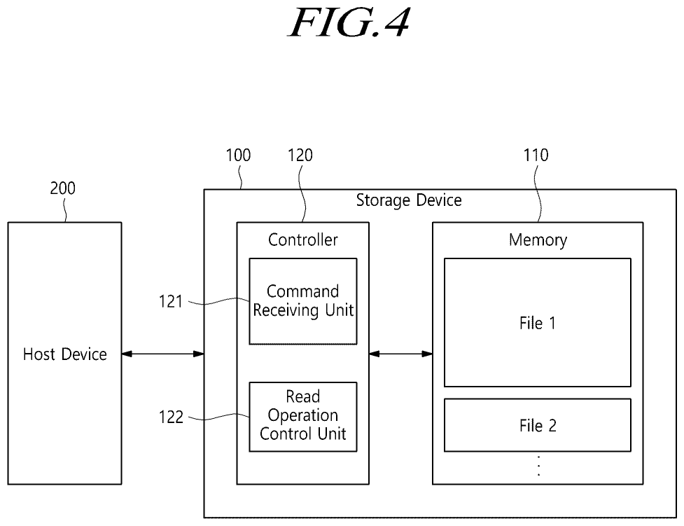

FIG. 4 is a diagram illustrating a configuration of a storage device 100 which performs a read retry operation by the unit of file, according to embodiments of the present disclosure.

Referring to FIG. 4, the storage device 100 may include a memory 110 and a controller 120. The memory 110 may be nonvolatile memory, but is not limited thereto. The controller 120 may control the operation of the memory 110 according to a command received from a host device 200.

The controller 120 may control an operation of writing data to the memory 110 or erasing data written to the memory 110. In addition, the controller 120 may control an operation of reading data written to the memory 110.

The controller 120 may include, for example, a command receiving unit (e.g., a command receiving circuit) 121 and a read operation control unit (e.g., a read operation control circuit) 122.

The command receiving unit 121 may receive a command transmitted by the host device 200. The command receiving unit 121 may receive a write command, a read command, etc. from the host device 200.

The command receiving unit 121 may receive the logical address of data according to a command. The logical address may be an address which is managed by the host device 200. The controller 120 may manage a physical address where data according to the logical address is stored, by mapping the logical address by the host device 200 and the physical address of the memory 110.

The command receiving unit 121 may receive, from the host device 200, information on a logical address and the length of data according to a command. When receiving a write command, the command receiving unit 121 may receive data according to the write command.

The command receiving unit 121 may receive, from the host device 200, information on a file according to a command. Data instructed to be written or read according to a command from the host device 200 may be a part of a file. The command receiving unit 121 may receive a logical address for data requested according to a command from the host device 200, and may also receive information on a file including the corresponding data.

For example, the command receiving unit 121 may receive, from the host device 200, information on the start logical address of a file according to a command and the length of data according to the corresponding file. In addition to information on a logical address and the length of data according to a command, the command receiving unit 121 may receive information on the start logical address of a file and the length of data according to the corresponding file. Alternatively, as the case may be, the command receiving unit 121 may receive only information on a file. A scheme in which information on a file to be received by the command receiving unit 121 is transmitted may follow, for example, the content defined in the Universal Flash Storage (UFS) standard.

For example, when receiving a write command, the command receiving unit 121 may receive the start logical address and length of a corresponding file through a write buffer command. After the corresponding file is written to the memory 110, the controller 120 may perform access to information on the corresponding file on the basis of the the start logical address and length of the corresponding file.

The command receiving unit 121 may receive information on a file according to a command from the host device 200, and the controller 120 may control the operation of the memory 110 using the information on the corresponding file.

According to a command received from the host device 200, the controller 120 may write data to the memory 110 or read data written to the memory 110. Since the controller 120 receives information on a file from the host device 200, the controller 120 may manage data to be stored in the memory 110 by the unit of file.

For example, FIG. 4 illustrates an example in which a first file and a second file are stored in the memory 110. As in the example illustrated in FIG. 4, data according to the first file and data according to the second file may be stored in the memory 110. An area where the data according to the first file is stored may be referred to as a first file storage area, and an area where the data according to the second file is stored may be referred to as a second file storage area.

The first file storage area may include, for example, at least one storage block BLK. Alternatively, a part of a storage block BLK may correspond to the first file storage area. The first file storage area may include a plurality of storage blocks BLK, and the plurality of storage blocks BLK may be or may not be physically adjacent to each other.

The second file storage area may be an area which is distinguished from the first file storage area. The size of the second file storage area may be different from the size of the first file storage area. The second file storage area may include at least one storage block BLK or may be a part of a storage block BLK.

Since the controller 120 receives, from the host device 200, information on a file to be written to the memory 110, the controller 120 may manage an area where data according to each file is stored, by using the corresponding information. When receiving a read command from the host device 200, the controller 120 may perform a read operation by checking information on a file requested according to the read command. When a read operation on each file fails, the controller 120 may control a read retry operation on the basis of the information on the file.

For example, the read operation control unit 122 may control a read operation using a read command received from the host device 200 and information on the start logical address of a file according to the read command and the length of data according to the file. The read operation control unit 122 may check the physical address of an area where each file is stored and perform a read operation on the corresponding area.

The read operation control unit 122 may perform a read operation using a constant read voltage for a file storage area where data according to each file is stored. For example, the read operation control unit 122 may perform a read operation using a first read voltage on the first file storage area where the first file is stored in the memory 110. The read operation control unit 122 may perform a read operation using a second read voltage on the second file storage area where the second file is stored in the memory 110.

The second read voltage may be the same voltage as or a different voltage from the first read voltage.

Since the characteristics of memory cells included in an area where data according to each file is stored may be considered to be similar, the read operation control unit 122 may adjust a read voltage for a read operation for each file storage area where each file is stored. Since a read voltage is managed for each file storage area, a load for managing read voltages may be reduced, and the efficiency of a read operation on each file may be improved.

When a read operation fails while performing the read operation on each file, the read operation control unit (e.g., read operation control circuit) 122 may perform a read retry operation on each area where the corresponding file is stored, thereby reducing delay due to the read retry operation and improving the performance of the read operation. In some embodiments, the read operation control circuit 122 may control one or more first read operations using a first read voltage on a first portion of a first file storage area storing the first file. When a specific one of the first read operations fails, the read operation control circuit 122 may search for a second read voltage and control one or more second read operations using the second read voltage on a second portion of the first file storage area other than the first portion. In addition, when performing one or more third read operations on the first file storage area according to a new read command, the read operation control circuit 122 may start the third read operations using either one of the first read voltage and the second read voltage.

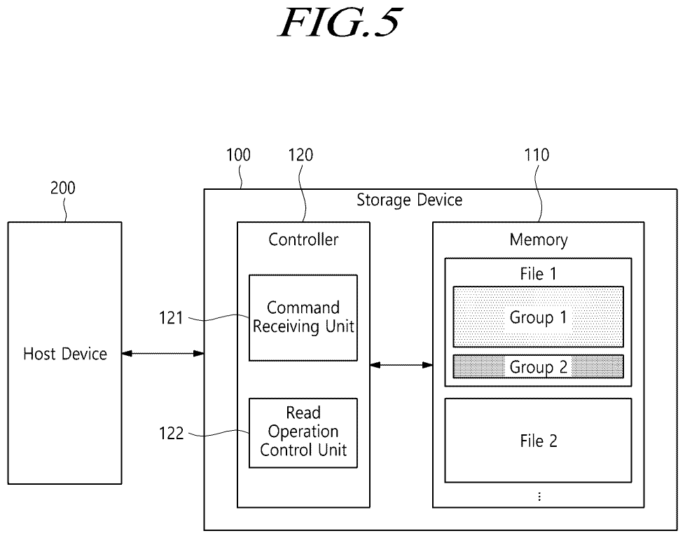

FIGS. 5, 6, 7, and 8 are diagrams each illustrating a method in which a read retry operation is performed by the storage device 100 illustrated in FIG. 4, according to embodiments of the present disclosure.

Referring to FIG. 5, an example is illustrated in which a first file and a second file are stored in the memory 110 of the storage device 100. The controller 120 of the storage device 100 may receive a read command from the host device 200. The controller 120 may receive information on the start logical address of a file requested according to the read command and the length of data. The controller 120 may check an area where the corresponding file is stored, on the basis of the received information on the file.

For example, the controller 120 may receive a read command for the first file from the host device 200. The controller 120 may check a first file storage area where the first file is stored in the memory 110. The controller 120 may perform a read operation on the first file storage area.

For example, the controller 120 may perform a read operation using a first read voltage preset for the first file storage area. The first read voltage may be a voltage which is to be applied to a word line WL as a read target. The first read voltage may be a voltage which is set as an initial read voltage or may be a voltage which is previously used when a read operation succeeds.

When the read operation using the first read voltage on the first file storage area does not fail, the controller 120 may complete the read operation on the first file storage area using the first read voltage.

When the read operation on the first file storage area fails, the controller 120 may perform a read operation using a new read voltage. The new read voltage may be, for example, a read voltage which may enable a read operation to succeed for a word line WL on which a read operation has failed. The controller 120 may set the new read voltage using a read voltage included in a read retry table stored in advance, or may search for the new read voltage within a predetermined range from the failed read voltage.

When the read operation using the first read voltage fails, the controller 120 may set a second read voltage as a new read voltage. The controller 120 may perform a read operation using the second read voltage on the word line WL on which the read operation by the first read voltage has failed. The controller 120 may perform the read operation on the first file storage area using the second read voltage which is the new read voltage, until a read operation on the first file storage area is terminated.

For example, referring to the example illustrated in FIG. 5, the controller 120 may perform a read operation using a first read voltage on a first group of the first file storage area included in the memory 110. Specifically, the controller 120 may perform one or more first read operations using a first read voltage on a first portion (e.g., a first group Group 1 in FIG. 5) of the first file storage area. The read operation based on the first read voltage may be performed on a word line WL which is included in the first group.

The controller 120 may fail in the read operation using the first read voltage. The controller 120 may search for a second read voltage with which a read operation may succeed. Specifically, the controller 120 may, when a specific one of the first read operations fails, search for a second read voltage.

When the second read voltage is searched for, the controller 120 may perform a read operation using the second read voltage. The controller 120 may perform the read operation based on the second read voltage on at least a part of a remaining area on which a read operation is not performed in the first file storage area.

For example, the controller 120 may perform the read operation using the second read voltage on a second group of the first file storage area. Specifically, the controller 120 may perform one or more second read operations using the second read voltage on a second portion (e.g., a second group Group 2 in FIG. 5) of the first file storage area other than the first portion. The read operation based on the second read voltage may be performed on a word line WL which is included in the second group.

For example, the controller 120 may succeed in the read operation using the first read voltage on the first group of the first file storage area, and may fail in the read operation using the first read voltage when performing a read operation on the second group. The controller 120 may search for a second read voltage and perform a read operation on the second group using the second read voltage.

Since the controller 120 sets and manages, by the unit of file, a read retry operation and a read voltage according to the read retry operation, delay due to the read retry operation may be reduced.

In order to manage a read voltage according to a read retry operation by the unit of file, the controller 120 may set a file history read flag.

For example, during a period in which the read operation is performed using the first read voltage on the first file storage area, the controller 120 may set the file history read flag for the first file or the first file storage area to a first value. Specifically, the controller 120 may set a file history read flag to a first value while performing the one or more first read operations using the first read voltage. The first value may be, for example, ‘0,’ but is not limited thereto.

When the read operation using the first read voltage on the first file storage area fails and a read operation on the remainder of the first file storage area is performed by searching for the second read voltage, the controller 120 may set the file history read flag for the first file or the first file storage area to a second value. Specifically, if a specific one of the first read operations using the first read voltage fails, the controller 120 may set the file history read flag to a second value while performing the one or more second read operations using the second read voltage. The second value may be, for example, ‘1,’ but is not limited thereto.

The controller 120 may manage a read voltage for the first file storage area on the basis of the file history read flag. When a read operation on the first file is completed, the controller 120 may set a history read voltage for the first file or the first file storage area on the basis of the file history read flag.

For example, when a read operation on the first file storage area is completed and the file history read flag is the first value, the controller 120 may set the history read voltage for the first file or the first file storage area to the first read voltage. Specifically, the controller 120 may check the file history read flag when a plurality of read operations performed on the first file storage area are completed, and set the first read voltage as a history read voltage for the first file storage area when the file history read flag is the first value. When a read operation on the first file storage area is completed and the file history read flag is the second value, the controller 120 may set the history read voltage for the first file or the first file storage area to the second read voltage. Specifically, the controller 120 may check the file history read flag when a plurality of read operations performed on the first file storage area are completed, and set the second read voltage as the history read voltage for the first file storage area when the file history read flag is the second value.

The history read voltage set for the first file or the first file storage area may be used when a read operation on the first file is performed according to a new read command.

When the read operation using the second read voltage on the first file storage area fails, the controller 120 may perform a read operation using a new read voltage.

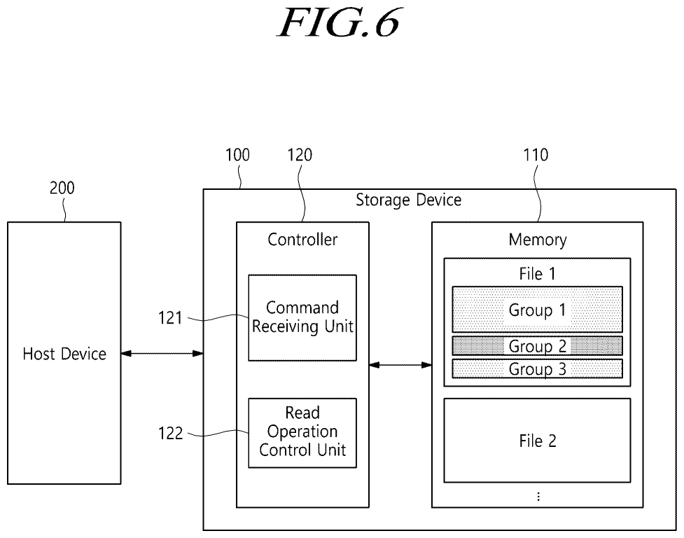

For example, referring to FIG. 6, the controller 120 may perform a read operation on a first file according to a read command received from the host device 200. The controller 120 may perform the read operation using a preset first read voltage on a first file storage area where data according to the first file is stored.

When the read operation based on the first read voltage fails, the controller 120 may search for a second read voltage and perform a read operation based on the second read voltage.

For example, the controller 120 may perform the read operation using the first read voltage on a first group of the first file storage area, and may perform the read operation using the second read voltage on a second group of the first file storage area. The controller 120 may set a file history read flag to a first value during a period in which the read operation is performed on the first group, and may set the file history read flag to a second value during a period in which the read operation is performed on the second group.

The controller 120 may fail in the read operation based on the second read voltage. When the read operation based on the second read voltage fails, the controller 120 may perform a read operation based on the first read voltage again on at least a part of an area where a read operation is not performed in the first file storage area. In some embodiments, when a specific one of the second read operations using the second read voltage fails, the controller 120 may perform one or more third read operations using the first read voltage on a third portion (e.g., a third group Group 3 in FIG. 6) of the first file storage area.

For example, the controller 120 may perform the read operation based on the first read voltage on a third group of the first file storage area. The read operation may be performed while the first read voltage is applied to a word line WL which is included in the third group of the first file storage area.

While the read operation on the third group is performed, the controller 120 may set the file history read flag to the first value. When a read operation on the first file storage area is completed, the controller 120 may set a history read voltage for the first file or the first file storage area to the first read voltage. A read voltage which is used in a last read operation on the first file storage area may be set as the history read voltage. For example, when a plurality of read operations performed on the first file storage area are completed, the controller 120 may store a read voltage used in a last one of the plurality of read operations on the first file storage area as a history read voltage for the first file storage area.

Alternatively, the controller 120 may set a read voltage with highest usage frequency during a read operation on the first file storage area as the history read voltage. Specifically, when a plurality of read operations performed on the first file storage area are completed, the controller 120 may store a read voltage with a highest usage frequency during the plurality of read operations are performed on the first file storage area as a history read voltage for the first file storage area. For example, the controller 120 may set the first read voltage as the history read voltage when the first read voltage has highest usage frequency during the read operation on the first file storage area, and may set the second read voltage as the history read voltage when the second read voltage has highest usage frequency during the read operation on the first file storage area.

As the controller 120 performs a read retry operation by the unit of file in a file storage area where a file is stored, delay due to the read retry operation may be reduced, and the performance of a read operation may be improved.

Alternatively, when the read operation based on the second read voltage fails, the controller 120 may perform a read operation using a new read voltage other than the first read voltage.

For example, the controller 120 may perform the read operation using the second read voltage on the second group of the first file storage area. When the read operation based on the second read voltage fails, the controller 120 may search for a third read voltage. For example, when a specific one of the second read operations using the second read voltage fails, the controller 120 may search for a third read voltage using the second read voltage.

The third read voltage may be, for example, one of voltages set in a read retry table. Alternatively, the third read voltage may be a voltage which is searched for within a predetermined range from the second read voltage on the basis of the second read voltage.

The controller 120 may perform a read operation on the third group of the first file storage area using the third read voltage. For example, the controller 120 may perform one or more third read operations using the third read voltage on a third portion (e.g., a third group Group 3 in FIG. 6) of the first file storage area.

The controller 120 may search for the third read voltage immediately when the read operation using the second read voltage fails, or may first perform a read operation using the first read voltage and then search for the third read voltage when the corresponding read operation fails.

The controller 120 may perform a read operation on a file storage area using one or two read voltages, or, as in the example described above, may perform a read operation on a file storage area using three or more read voltages. Even in a case where a plurality of read voltages are used, since a read retry operation is performed by the unit of group in a file storage area and a new read voltage is set, delay due to the read retry operation may be reduced.

In this case, the history read voltage for the first file or the first file storage area may be set as a voltage used in a last read operation, or may be set as a voltage with highest usage frequency in a read operation on the first file storage area.

The controller 120 may perform a read operation and a read retry operation by the unit of file, and may perform a read operation in a similar manner even on an area where a second file, which is distinct from the first file, is stored.

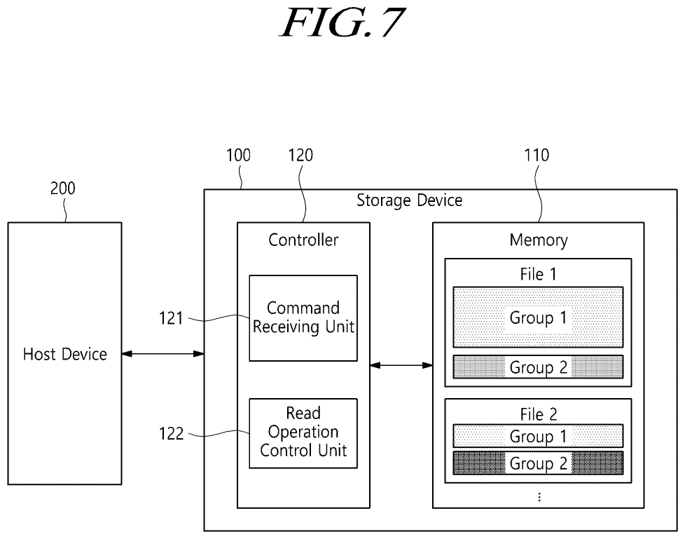

For example, referring to FIG. 7, according to a read command for a first file from the host device 200, the controller 120 may perform a read operation on a first file storage area where data according to the first file is stored in the memory 110. The controller 120 may perform a read operation using a first read voltage on a first group of the first file storage area. When the read operation by the first read voltage fails, the controller 120 may search for a second read voltage. The controller 120 may perform a read operation based on the second read voltage on a second group of the first file storage area.

When a read operation on the first file storage area is terminated, the controller 120 may set a history read voltage for the first file or the first file storage area to the second read voltage. Specifically, when a plurality of read operations performed on the first file storage area are completed, the controller 120 may store the second read voltage as a history read voltage for the first file storage area. As the case may be, a read voltage with highest usage frequency during a read operation on the first file storage area may be set as the history read voltage for the first file or the first file storage area.

According to a read command for a second file from the host device 200, the controller 120 may perform a read operation on a second file storage area of the memory 110.

The second file storage area may be an area where data according to the second file is stored. The second file storage area may be an area which is distinct from the first file storage area.

The controller 120 may perform a read operation based on a third read voltage on the second file storage area. When the read operation based on the third read voltage on the second file storage area fails, the controller 120 may search for a fourth read voltage. The controller 120 may perform a read operation based on the fourth read voltage on at least a part of a remaining area where a read operation is not performed in the second file storage area. Specifically, the controller 120 may perform one or more third read operations on a first portion (Group 1 in FIG. 7) of a second file storage area using a third read voltage, the second file storage area storing a second file. When a specific one of the third read operations fails, the controller 120 may perform one or more fourth read operations on a second portion (e.g., Group 2 in FIG. 7) of the second file storage area using a fourth read voltage. In some embodiments, the third read voltage may be substantially equal to the first read voltage, and the fourth read voltage may be substantially equal to the second read voltage.

For example, the controller 120 may perform the read operation based on the third read voltage on a first group of the second file storage area. The controller 120 may perform the read operation based on the fourth read voltage on a second group of the second file storage area.

When performing the read operation based on the third read voltage, the controller 120 may set a file history read flag for the second file or the second file storage area to a first value. When performing the read operation based on the fourth read voltage, the controller 120 may set the file history read flag for the second file or the second file storage area to a second value.

When a read operation on the second file storage area is terminated, the controller 120 may set the third read voltage or the fourth read voltage as a history read voltage for the second file or the second file storage area.

The third read voltage which is used in an initial read operation on the second file storage area may be the same as the first read voltage which is used in an initial read operation on the first file storage area. The first read voltage and the third read voltage may be a voltage which is set for an initial read operation.

Alternatively, the third read voltage may be a voltage which is different from the first read voltage. The first read voltage and the third read voltage may be history read voltages for the first file storage area and the second file storage area, respectively.

The fourth read voltage which is used by being changed for the second file storage area may be the same as the second read voltage which is used by being changed for the first file storage area. When the third read voltage and the first read voltage are the same, the fourth read voltage may also be set to be the same as the second read voltage.

Alternatively, the fourth read voltage may be different from the second read voltage. When the third read voltage is different from the first read voltage, the fourth read voltage may also be set to be different from the second read voltage.

Alternatively, even in a case where the third read voltage is the same as the first read voltage, depending on the characteristics of the second file storage area, a read voltage different from a new read voltage set for the first file storage area may be set as a voltage for a read retry operation on the second file storage area.

On the basis of information on a file received from the host device 200, the controller 120 may perform a read retry operation on each area where the file is stored in the memory 110.

When a new file is written to a corresponding area, the controller 120 may control a read retry operation similarly to the method described above, or may use an existing history read voltage.

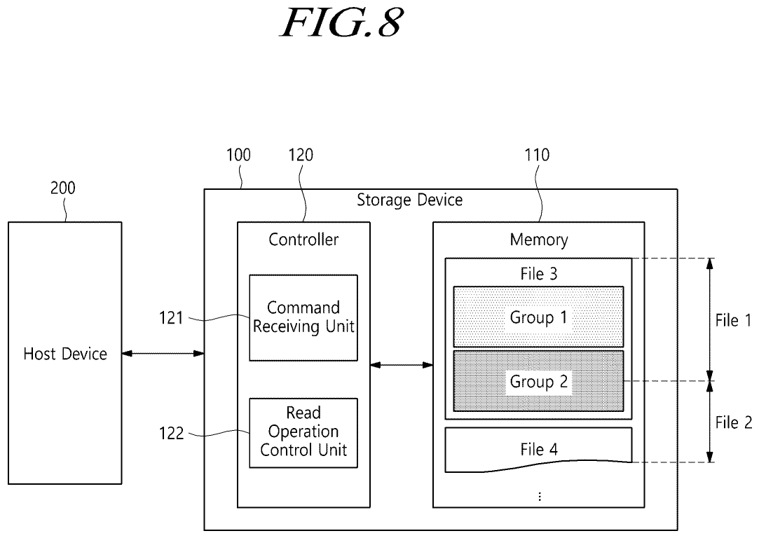

For example, referring to FIG. 8, an example is illustrated in which data according to a third file and a fourth file are stored in the memory 110. A third file storage area where data according to the third file is stored may include a first file storage area where a first file has been previously stored. The third file storage area may include a part of a second file storage area where a second file has been previously stored.

A fourth file storage area where data according to the fourth file is stored may include a part of the second file storage area where the second file has been previously stored.

The controller 120 may receive a read command for the third file from the host device 200. On the basis of information on the third file, the controller 120 may check the third file storage area where the data according to the third file is stored in the memory 110.

The controller 120 may perform a read operation based on a first read voltage on the third file storage area where the third file is stored. The first read voltage may be a voltage which is set as an initial read voltage. Alternatively, the first read voltage may be a history read voltage previously set for the first file storage area.

When the read operation based on the first read voltage fails, the controller 120 may search for a second read voltage. After searching for the second read voltage, the controller 120 may perform a read operation based on the second read voltage on at least a part of a remaining area where a read operation is not performed.

For example, the controller 120 may perform the read operation based on the first read voltage on a first group of the third file storage area, and may perform the read operation based on the second read voltage on a second group of the third file storage area.

When searching for the second read voltage, the controller 120 may use a read retry voltage which is set in a read retry table. Alternatively, when searching for the second read voltage, the controller 120 may use a history read voltage for the corresponding file storage area.

For example, when searching for a new read voltage for the second group in the third file storage area, the controller 120 may search for the new read voltage using a history read voltage previously set for the first file storage area.

Alternatively, when an area which previously corresponds to the second file storage area is larger than an area included in the second group in the third file storage area, the controller 120 may search for a new read voltage using the history read voltage previously set for the second file storage area.

Even in a case where a file written to a storage area of the memory 110 is changed, the controller 120 may increase efficiency of a read retry operation through a read retry operation by the unit of file using the first read voltage and the second read voltage set to the same default values as before. Alternatively, as in the example described above, efficiency of searching for a new read voltage may be increased by using a history read voltage which has been set for a previous file storage area corresponding to a corresponding file storage area.

The aforementioned read retry operation by the unit of file may be performed by the unit of word line WL in each file storage area. Each group of a file storage area which is distinguishable by a read voltage may include at least one word line WL, and when performing a read operation on each word line WL, a read voltage may be controlled depending on whether the read operation succeeds.

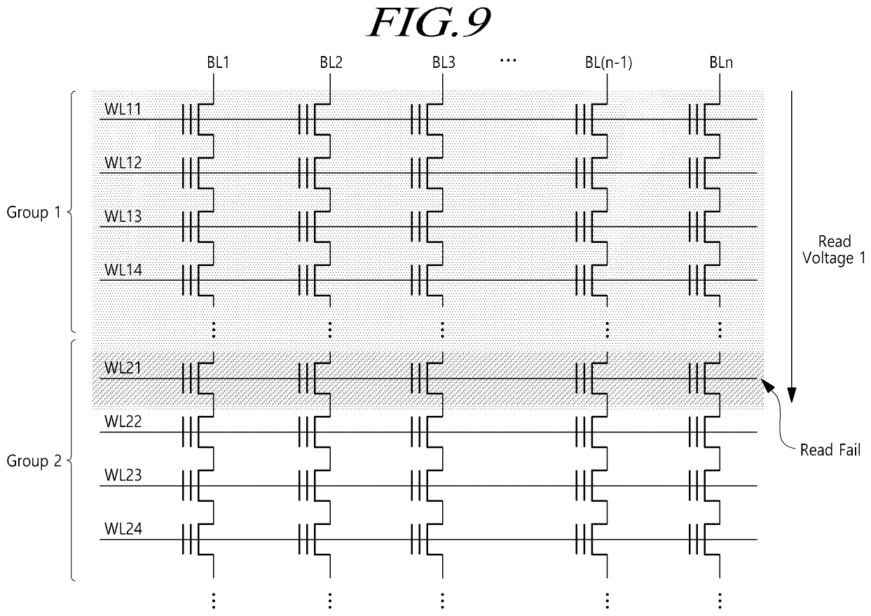

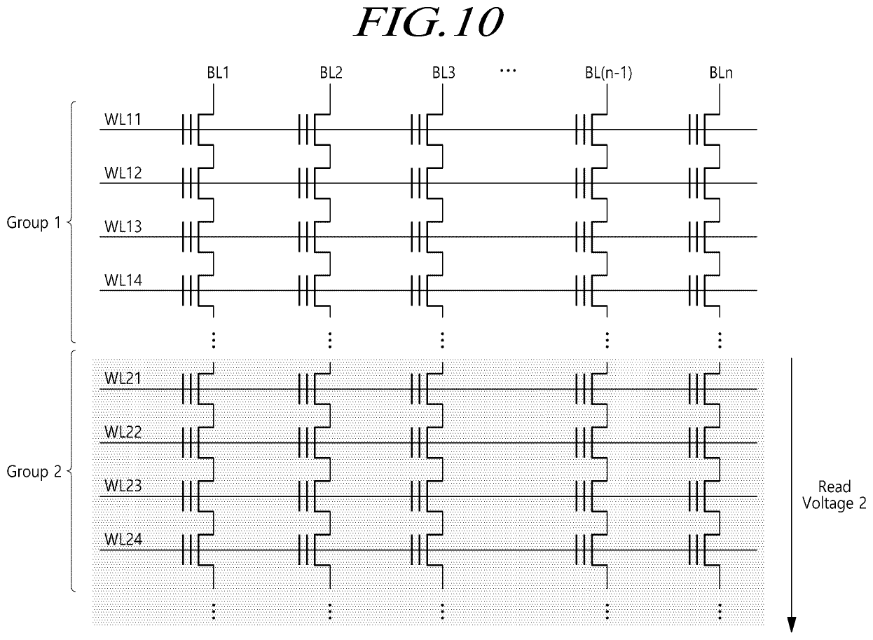

FIG. 9 and FIG. 10 are diagrams each illustrating examples of a method in which a read retry operation is performed in the memory 110 of the storage device 100 illustrated in FIG. 4 according to embodiments of the present disclosure.

Referring to FIG. 9 and FIG. 10, memory cells which are included in a file storage area where data according to the same file is stored are illustrated as an example. A plurality of word lines WL and a plurality of bit lines BL may be included in the file storage area. The plurality of word lines WL may be divided into a first group and a second group depending on a read voltage used in one or more read operations.

For example, a plurality of word lines WL11, WL12, WL13, WL14, . . . may be included in a first group of the file storage area. A plurality of word lines WL21, WL22, WL23, WL24, . . . may be included in a second group of the file storage area.

The controller 120 may sequentially perform a read operation on the word lines WL11, WL12, WL13, WL14, . . . of the first group using a first read voltage. The controller 120 may fail in a read operation using the first read voltage on the word line WL21. Specifically, the controller 120 may perform a plurality of first read operations on a plurality of word lines included in the first file storage area, respectively, until a specific one of the first read operations fails on a first word line (e.g., WL21 in FIG. 9) among the plurality of word lines.

The controller 120 may search for a new read voltage for the word line WL21. The controller 120 may succeed in a read operation on the word line WL21 using a second read voltage.

The controller 120 may perform a read operation on the word lines WL21, WL22, WL23, WL24, . . . included in the second group using the second read voltage, which is a new read voltage. Specifically, when the specific one of the first read operation fails, the controller 120 may search for a new read voltage (e.g., the second read voltage) with which a first one of a plurality of second read operations on the first word line WL21 succeeds. The controller 120 may perform a second one of the second read operations on a second word line (e.g., WL22) on which a read operation subsequent to the first one of the second read operations is to be performed.

While performing the read operation on the second group using the second read voltage, the controller 120 may set the value of a file history read flag by changing the value from a first value to a second value. When the read operation using the second read voltage fails, the controller 120 may perform a read operation using the first read voltage again, or may perform a read operation using a new third read voltage.

When a read operation on the file storage area for the corresponding file is terminated, the controller 120 may set a read voltage used in a last read operation as a history read voltage. Alternatively, a read voltage with a highest usage frequency in the file storage area may be set as a history read voltage.

Thereafter, when performing a read operation on a file storage area according to a new read command, the controller 120 may start a read operation using the history read voltage.

For example, in a case where the second read voltage is set as the history read voltage for a corresponding file storage area, when performing a new read operation, a read operation may be started using the second read voltage on the word lines WL11, WL12, WL13, WL14, . . . included in the first group. Specifically, when performing one or more new read operations for the file according to a new read command, the controller 120 may perform the new read operations using a given voltage (e.g., the second voltage) on the word lines on which the first read operations have been previously performed.

According to the embodiments of the present disclosure described above, in an operation according to a read command, on the basis of information on a file received from the host device 200, a read voltage may be controlled to perform a read retry operation by the unit of a file storage area where data according to the corresponding file is stored. Therefore, delay due to the read retry operation may be reduced, and the performance of a read operation of the storage device 100 may be improved.

Although some embodiments of the present disclosure have been described above with particular specifics and varying details for illustrative purposes, those skilled in the art will appreciate that various modifications, additions and substitutions may be made based on what is disclosed or illustrated in the present disclosure.

What is claimed is:

1. A storage device comprising:
a memory including a first file storage area where a first file is stored; and
a controller configured to perform one or more first read operations using a first read voltage on a first portion of the first file storage area and configured to, when a specific one of the first read operations fails, search for a second read voltage and perform one or more second read operations using the second read voltage on a second portion of the first file storage area other than the first portion.

2. The storage device according to claim 1, wherein when a specific one of the second read operations using the second read voltage fails, the controller performs one or more third read operations using the first read voltage on a third portion of the first file storage area.

3. The storage device according to claim 1, wherein when a specific one of the second read operations using the second read voltage fails, the controller searches for a third read voltage using the second read voltage and performs one or more third read operations using the third read voltage on a third portion of the first file storage area.

4. The storage device according to claim 1, wherein a plurality of read operations including the one or more first operations and the one or more second operations are performed on the first file storage area according to a read command for the first file, and
wherein when the plurality of read operations performed on the first file storage area are completed, the controller stores the second read voltage as a history read voltage for the first file storage area.

5. The storage device according to claim 1, wherein a plurality of read operations including the one or more first operations and the one or more second operations are performed on the first file storage area according to a read command for the first file, and
wherein when the plurality of read operations performed on the first file storage area are completed, the controller stores a read voltage used in a last one of the plurality of read operations on the first file storage area as a history read voltage for the first file storage area.

6. The storage device according to claim 1, wherein a plurality of read operations including the one or more first operations and the one or more second operations are performed on the first file storage area according to a read command for the first file, and
wherein when the plurality of read operations performed on the first file storage area are completed, the controller stores a read voltage with a highest usage frequency during the plurality of read operations are performed on the first file storage area as a history read voltage for the first file storage area.

7. The storage device according to claim 1, wherein the controller sets a file history read flag to a first value while performing the one or more first read operations using the first read voltage, and sets the file history read flag to a second value while performing the one or more second read operations using the second read voltage.

8. The storage device according to claim 7, wherein a plurality of read operations including the one or more first operations and the one or more second operations are performed on the first file storage area according to a read command for the first file, and
wherein the controller checks the file history read flag when the plurality of read operations performed on the first file storage area are completed, sets the first read voltage as a history read voltage for the first file storage area when the file history read flag is the first value, and sets the second read voltage as the history read voltage for the first file storage area when the file history read flag is the second value.

9. The storage device according to claim 1, wherein when receiving a read command for the first file, the controller obtains information on a start logical block address for the first file and a length of data according to the first file.

10. The storage device according to claim 1, wherein the controller performs the first read operations on a plurality of word lines included in the first file storage area, respectively, until a specific one of the first read operations fails on a first word line among the plurality of word lines, and
wherein when the specific one of the first read operations fails, the controller searches for the second read voltage with which a first one of the second read operations on the first word line succeeds.

11. The storage device according to claim 10, wherein the controller performs a second one of the second read operations on a second word line on which a read operation subsequent to the first one of the second read operations is to be performed.

12. The storage device according to claim 10, wherein when performing a new read operation for the first file, the controller performs the new read operation using the second read voltage on a second word line among the plurality of word lines on which the first read operations have been performed.

13. The storage device according to claim 1, wherein the controller performs one or more third read operations on a first portion of a second file storage area using the first read voltage, the second file storage are storing a second file, and when a specific one of the third read operations fails, performs one or more fourth read operations on a second portion of the second file storage area using the second read voltage.

14. A memory device comprising:
a first file storage area including a plurality of first word lines and storing a first file therein; and
a second file storage area including a plurality of second word lines and storing a second file therein,
wherein, according to a first read command for the first file, one or more first read operations using a first read voltage are performed on a first group of the plurality of first word lines, and one or more second read operations using a second read voltage is performed on a second group of the plurality of first word lines.

15. The memory device according to claim 14, wherein after a specific one of the first read operations has been performed on a first word line in the second group of the plurality of first word lines, a first one of the second read operations is performed on the first word line.

16. The memory device according to claim 14, wherein when performing a new read operation for the first file, one or more third read operations using the second read voltage are performed on the first group of the plurality of first word lines.

17. The memory device according to claim 14, wherein according to a second read command for the second file, one or more third read operations using a third read voltage are performed on a first group of the plurality of second word lines, and one or more fourth read operations using a fourth read voltage are performed on a second group of the plurality of second word lines.

18. The memory device according to claim 17, wherein the third read voltage is the same as the first read voltage, and the fourth read voltage is different from the second read voltage.

19. A controller comprising:
a command receiving circuit configured to receive a read command and information on a file according to the read command; and
a read operation control circuit configured to control one or more first read operations using a first read voltage on a first portion of a first file storage area storing the file, and configured to, when a specific one of the first read operations fails, search for a second read voltage and control one or more second read operations using the second read voltage on a second portion of the first file storage area other than the first portion.

20. The controller according to claim 19, wherein when performing one or more third read operations on the first file storage area according to a new read command, the read operation control circuit starts the third read operations using either one of the first read voltage and the second read voltage.
